(19) United States
(12) Patent Application Publication
(10) Pub. No.: US 2024/0147770 A1
(43) Pub. Date: May 2, 2024

(54) DISPLAY PANEL AND DISPLAY DEVICE

(71) Applicant: KunShan Go-Visionox Opto-Electronics Co., Ltd, Kunshan (CN)

(72) Inventors: Jishuai ZHANG, Kunshan (CN); Gongzheng ZANG, Kunshan (CN); Wenxing LI, Kunshan (CN); Yaolong DONG, Kunshan (CN)

(73) Assignee: KunShan Go-Visionox Opto-Electronics Co., Ltd, Kunshan (CN)

(21) Appl. No.: 18/398,864

(22) Filed: Dec. 28, 2023

Related U.S. Application Data
(63) Continuation of application No. PCT/CN2022/122743, filed on Sep. 29, 2022.

(30) Foreign Application Priority Data
Jun. 10, 2022 (CN) 202210654374.X

(51) Int. Cl. H10K 59/122; H10K 59/80

(52) U.S. Cl. CPC H10K 59/122; H10K 59/873

(57) ABSTRACT

A display panel and a display device. The display panel includes a substrate; a pixel definition layer provided on the substrate, the pixel definition layer including an isolation structure and a plurality of pixel openings formed and enclosed by the isolation structure; a support assembly arranged on a side of the isolation structure facing away from the substrate, the support assembly including two or more support columns located between two adjacent pixel openings; a cover plate located on a side of the support assembly facing away from the pixel definition layer. Between the two adjacent pixel openings, the support assembly includes two or more support columns, which can provide sufficient support to the cover plate, thereby effectively improving the problem of the cover plate being prone to deformation, and thus improving the impact of the deformation of the cover plate on the display effect.

### CROSS-REFERENCE OF RELATED APPLICATIONS

The present application is a continuation of International Application No. PCT/CN2022/122743 filed on Sep. 29, 2022, which claims the priority of Chinese patent application No. 202210654374. X entitled “Display Panel and Display Device” and filed on Jun. 10, 2022, both of which are incorporated herein by reference in their entireties.

### TECHNICAL FIELD

The present application relates to the technical field of display apparatus, in particular to a display panel and a display device.

### BACKGROUND

Organic Light Emitting Diode (OLED) is an active light emitting device. Compared with the traditional display manner of Liquid Crystal Display (LCD), OLED display technology does not require backlight and has the characteristic of self-illumination. And it can be made lighter and thinner, can withstand a wider range of temperature changes than the LCD display panel, and has a larger viewing angle. The OLED display panel is expected to become the next generation of flat panel display technology after LCD, and is currently one of the most concerned technologies in flat panel display technology.

The OLED display panel consists of two main parts: a display substrate and a cover plate, and the display substrate and the cover plate are connected to each other through a packaging structure. A support column is provided on the display substrate, which serves for supporting the cover plate. In prior art, due to the action force of gravity and atmospheric pressure, the cover plate is prone to deformation. The light from the display substrate emits through the cover plate, and the deformation of the cover plate can affect the display effect.

### SUMMARY

Embodiments of the present application provide a display panel and a display device, aiming to solve the problem of the cover plate of the display panel being prone to deformation.

In a first aspect, embodiments of the present application provide a display panel, which includes a substrate; a pixel definition layer provided on the substrate, the pixel definition layer including an isolation structure and a plurality of pixel openings formed and enclosed by the isolation structure; a support assembly located on a side of the isolation structure facing away from the substrate and located between two adjacent pixel openings, at least part of the support assembly including two or more support columns spaced apart; a cover plate located on a side of the support assembly facing away from the pixel definition layer.

Embodiments of the present application in the second aspect further provides a display device, which includes a display panel of any of embodiments in the first aspect mentioned above.

In the display panel of the embodiments of the present application, the display panel includes a substrate, a pixel definition layer, a support assembly, and a cover plate. The pixel definition layer includes an isolation structure and a plurality of pixel openings for accommodating the light emitting material to achieve the light-emitting of the display panel. The support assembly is supported between the isolation structure and the cover plate, and is used to provide support force to the cover plate. Between the two adjacent pixel openings, the support assembly includes two or more support columns, which can provide sufficient support to the cover plate, thereby effectively improving the problem of the cover plate being prone to deformation, and thus improving the impact of the deformation of the cover plate on the display effect of the display panel.

### BRIEF DESCRIPTION OF THE DRAWINGS

FIG. 1 is a top view of a display panel provided in the embodiment of the present application in a first aspect;

FIG. 2 is a schematic diagram of the locally enlarged structure at I in FIG. 1 in an example;

FIG. 3 is a cross-sectional view at A-A in FIG. 2;

FIG. 4 is a schematic diagram of the locally enlarged structure at I in FIG. 1 in another example;

FIG. 5 is a schematic diagram of the locally enlarged structure at I in FIG. 1 in still another example;

FIG. 6 is a schematic diagram of the locally enlarged structure at I in FIG. 1 in yet another example;

FIG. 7 is a schematic diagram of the locally enlarged structure at I in FIG. 1 in further another example;

FIG. 8 is a schematic diagram of the locally enlarged structure at I in FIG. 1 in further another example;

FIG. 9 is a schematic diagram of the locally enlarged structure at I in FIG. 1 in further another example;

FIG. 10 is a schematic diagram of the locally enlarged structure at I in FIG. 1 in further another example.

### DETAILED DESCRIPTION

The directional words appearing in the following description are all the directions shown in the figures and are not intended to limit the specific structure of the embodiments of the present application. In the description of the present application, it should also be noted that unless otherwise specified and limited, the terms “installation” and “connection” should be broadly understood, for example, it can be fixed connection, detachable connection, or integrated connection; It can be direct connection or indirect connection. For the skilled person in the art, the specific meaning of the above terms in the present application can be understood according to specific circumstances.

The OLED display panel consists of two main parts: a display substrate and a cover plate and the display substrate is connected with the cover plate through an edge packaging structure. In addition, in order to prevent contact between the display substrate and the middle part of the cover plate, a support column with a certain extension height will be installed on the display substrate to support the cover plate and prevent damage to the light-emitting device caused by the cover plate.

Generally, multiple support columns provided on the display substrate are used to support the cover plate, but after a period of use, the display panel will experience Newton ring phenomenon, that is, an abnormal display ring area occurring in the zone of the display panel close to the edge, which seriously affects the display effect and the service life of the display panel.

The inventors found through research that this is due to abnormal display caused by deformation of the cover plate after a period of use. After a period of use, the cover plate undergoes deformation similar to a bathtub curve under the action of gravity and atmospheric pressure. The cover plate will recess toward the display substrate to form a curved surface with a certain radius of curvature. When light illuminates from the cover plate onto the display substrate, the optical path difference of different beams in the microcavity formed between the cover plate and the display substrate will be different. The reflected light generated by the upper and lower surfaces of the cover plate and the display substrate will interfere with each other, causing Newton ring phenomenon on the display panel, which affects the display effect of the product.

The inventors further studied and found that the Newton ring phenomenon occurs due to insufficient support force and poor deformation resistance of the supporting column. The deformation of the cover plate is caused by the deformation of part of the supporting columns. Furthermore, the inventors found that usually a support column body with a size that is adapted to the gap between the adjacent pixel openings is provided between the adjacent pixel openings. During the preparation process, due to the limitations of the preparation process, the support column body is prone to collapse and deformation after forming, resulting in a large difference between the actual shape and the design shape of the support column body. For example, the support column body is designed to be a columnar structure, and the final actual shape is a platform like structure after being affected by the process, which leads to insufficient support force of the supporting column body, so that the cover plate is prone to deform under the support force of the supporting column body.

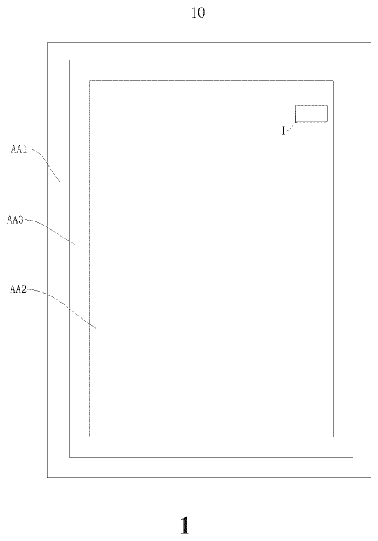

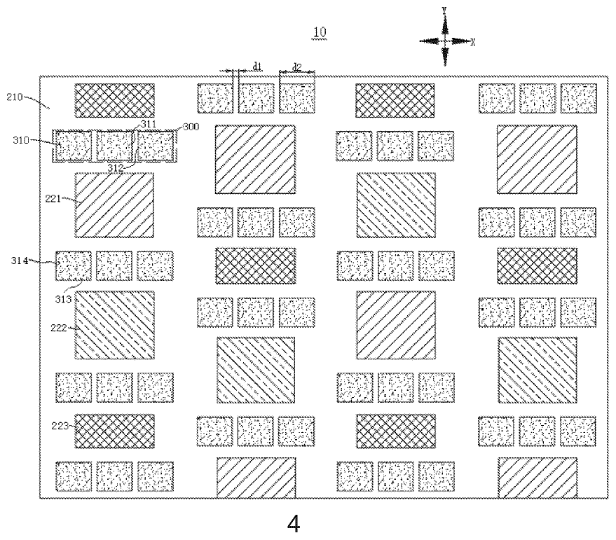

In order to solve the above technical problem, the present application is proposed. In order to better understand the present application, the display panel and display device of the embodiment of the present application will be described in detail in conjunction with FIGS. 1 to 10.

Please refer to FIGS. 1 to 3. According to the embodiment of the present application in the first aspect, the display panel 10 includes a substrate 100, a pixel definition layer 200, a support assembly 300, and a cover plate 400. The pixel definition layer 200 is provided on the substrate 100 and includes an isolation structure 210 and a plurality of pixel openings 220 formed and enclosed by the isolation structure 210; The support assembly 300 is provided on a side of the isolation structure 210 facing away from the substrate 100 and is located between two adjacent pixel openings 220 which are at least adjacent partially, and at least part of the support assembly 300 includes two or more support columns 310; The cover plate 400 is located on a side of the support assembly 300 facing away from the pixel definition layer 200.

In the embodiment of the present application, the display panel 10 includes a substrate 100, a pixel definition layer 200, a support assembly 300, and a cover plate 400. The pixel definition layer 200 includes an isolation structure 210 and a plurality of pixel openings 220 for accommodating the light emitting material to achieve the light-emitting of the display panel 10. The support assembly 300 is supported between the isolation structure 210 and the cover plate 400, and is used to provide support force to the cover plate 400. Between two adjacent pixel openings 220 which are at least adjacent partially, the support assembly 300 includes two or more support columns 310. The difference between the actual shape and the design shape of the support column 310 is small, ensuring sufficient contact area between the support column 310 and the cover plate 400, enabling two or more support columns 310 to provide sufficient support force to the cover plate 400, thereby effectively improving the problem of the cover plate 400 being prone to deformation and improving the impact of the deformation of the cover plate 400 on the display effect of the display panel 10.

In addition, compared to the solution of providing one support column 310 between two adjacent pixel openings 220 which are at least adjacent partially, the present application equivalently divides the support column 310 between the adjacent pixel openings 220 into plural, so that the gap distance between adjacent support columns 310 is small. When the support column 310 collapses and deforms after forming, due to the small gap distance, the adjacent two support columns 310 can limit each other, thereby reducing the collapse deformation of the support column 310, reducing the difference between the actual shape and the design shape of the support column 310, and enabling the support column 310 to provide sufficient support force to the cover plate 400.

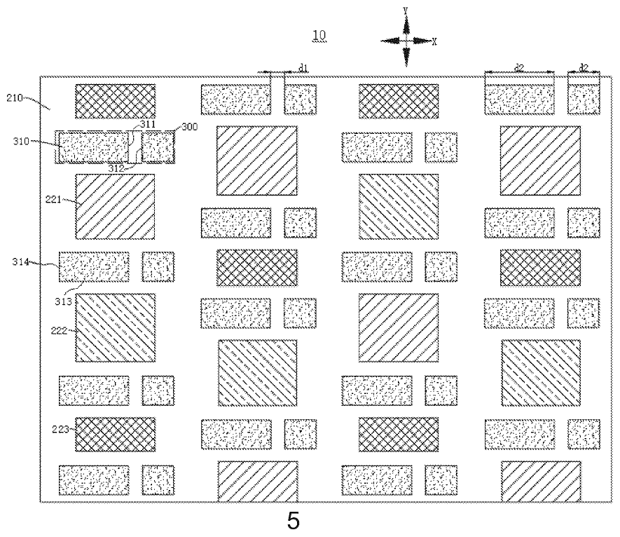

The number of the support column 310 within support assembly 300 can be two, or, as shown in FIG. 4, the number of the support column 310 within support assembly 300 can also be three. In other embodiments, the number of the support column 310 within the support assembly 300 can also be more.

The number of the support columns 310 within the support assembly 300 between two adjacent pixel openings 220 is 1, 2, and 3, respectively. When the number of the support column 310 within the support assembly 300 is 2 and 3, the total size of the support assembly 300 is the same as that of the support assembly 300 including one support column 310. The total deformation amount of the support column 310 is obtained as follows

| | the number of the support | the total deformation |
|---|---|---|
| | column within the support | amount of the support |
| | assembly | assembly |
| Example 1 | 1 | 8.05 nm |
| Example 2 | 2 | 7.46 nm |
| Example 3 | 3 | 7.29 nm |

The total deformation amount of the support assembly 300 refers to the total height deformation amount of the support assembly 300, that is, the deformation amount of the support assembly 300 in the thickness direction of the display panel 10. From the above table, it can be seen that when the support assembly 300 includes more than two support columns 310, the deformation amount of the support column 310 significantly decreases. Therefore, when the support assembly 300 includes more than two support columns 310, the deformation of the support column 310 can be improved effectively, the support force of the support assembly 300 can be increased, and the deformation of the cover plate 400 can be improved.

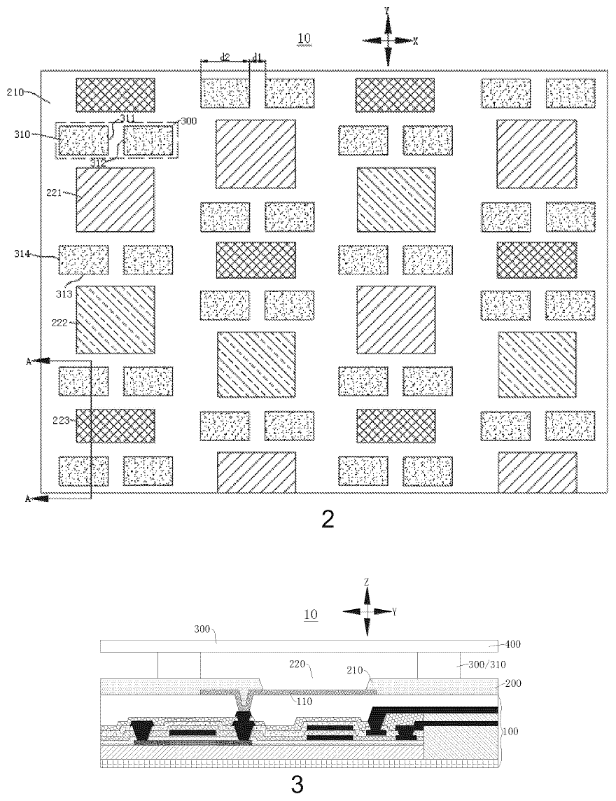

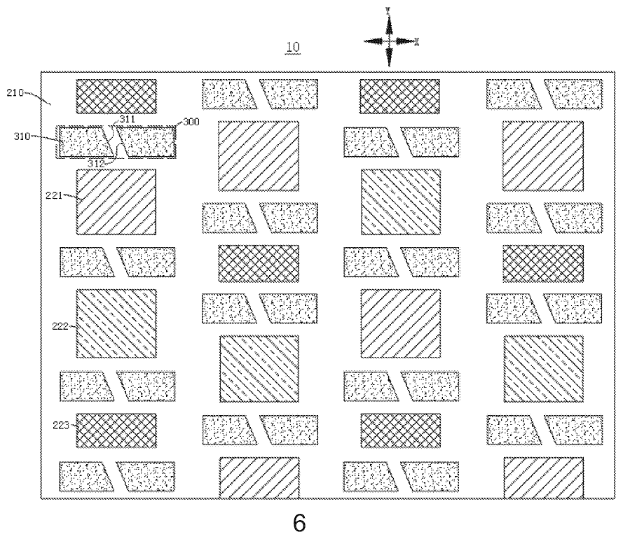

Optionally, when the support assembly 300 includes two or more support columns 310, the sizes of the two or more support columns 310 may be the same or different. As shown in FIG. 2, the support assembly 300 includes two or more support columns 310 with the same size. Alternatively, as shown in FIG. 5, the support assembly 300 includes two or more support columns 310 with different structures.

There are various ways to provide the substrate 100. The substrate 100 can include a substrate and an array substrate. The array substrate can include a thin film transistor and a signal line, and the signal line can include data line, scanning line, power line and other signal lines.

Optionally, a plurality of pixel electrodes 110 are further provided on the substrate 100, and the orthographic projection of the pixel electrodes 110 on the substrate 100 and the orthographic projection of the pixel openings 220 on the substrate 100 are at least partially overlapped, so that the pixel electrodes 110 can drive the light emitting material inside the pixel openings 220 to emit light.

Optionally, a light emitting unit can be provided inside the pixel opening 220. The light emitting unit includes a light emitting material and is used for light emitting display. Optionally, a common electrode can be further provided on a side of the support assembly facing away from the pixel definition layer 200. The common electrode and the pixel electrode 110 are cooperated to drive the light emitting unit to emit light.

Optionally, a plurality of light emitting units include a plurality of red light emitting units for emitting red light, a plurality of blue light emitting units for emitting blue light, and a plurality of green light emitting units for emitting green light. The pixel openings 220 include a plurality of first pixel openings 221 for accommodating a plurality of red light emitting units, a plurality of second pixel openings 222 for accommodating a plurality of blue light emitting units, and a plurality of third pixel openings 223 for accommodating a plurality of green light emitting units. In other embodiments, the plurality of light emitting units may further include a plurality of light emitting units for emitting light of other colors, and the pixel openings 220 may further include a plurality of light emitting units for accommodating other colors of light emitting units.

In some optional embodiments, please continue to refer to FIGS. 2 to 5. The support assembly 300 has a first spacing d1 between at least two adjacent support columns 310 along a first direction X. The extension size of the support column 310 in the first direction is d2, and the first spacing d1 meets 0.15d2≤d1≤0.25d2.

In these optional embodiments, d1≤0.15d2 can improve the difficulty in preparing the support column 310 caused by d1 being too small; d1≤0.0.25d2 can improve the insufficient position-limiting between adjacent support columns 310 caused by d1 being too large. The too large deformation of the support column 310 results in a too large difference between the actual shape and the design shape, so that the support column 310 cannot provide sufficient support to the cover plate 400.

When the support assembly 300 includes multiple support columns 310, d2 can take the extension size of any support column 310 within the support assembly 300 in the first direction X. Optionally, d2 takes the extension size in the first direction of either of the two support columns 310 located at the first spacing d1 on both sides of the first direction. Optionally, d2 takes the average extension size in the first direction of the two support columns 310 on both sides of the first direction X at the first spacing d1.

Assuming that the extension size of the support column 310 in the first direction X is 16 μm, the sizes of the two adjacent support columns 310 in the first direction X are equal, and the first spacing d1 between the two adjacent support columns 310 in the first direction X is set to 1 μm, 2 μm, 3 μm, 4 μm, and 5 μm respectively, the deformation amount of the cover plate 400 is shown in the table below:

| | | the deformation amount of |
|---|---|---|
| | the first spacing | the cover plate |
| Example 4 | 1 μm | 2.349 nm |
| Example 5 | 2 μm | 2.342 nm |
| Example 6 | 3 μm | 1.270 nm |
| Example 7 | 4 μm | 2.352 nm |
| Example 8 | 5 μm | 2.342 nm |

According to the above table, when the value of the first spacing d1 is 1 μm, 2 μm, 4 μm and 5 μm, the deformation amount of the cover plate 400 is relatively large. When the value of the first spacing d1 is 3 μm, that is, when 0.15d2≤d1≤0.25d2, the deformation amount of the cover plate 400 is the smallest.

Optional, the first spacing d1 is 2.5 μm-3.5 μm, which can improve the deformation of the cover plate 400 caused by the insufficient support force of the support column 310 due to the first spacing d1 being too large or too small.

Optionally, the number of the support assemblies 300 is two or more, and the spacing between two adjacent support columns 310 in each support assembly 300 in the first direction X meets 0.15d2≤d1≤0.25d2.

Alternatively, in other embodiments, along the direction from the center to the edge of the display panel 10, the absolute value of the difference between the first spacing d1 and the preset spacing value d gradually decreases in at least some areas, and the preset spacing value d is 0.2d2.

In these optional embodiments, along the direction from the center to the edge of the display panel 10, the value of the first spacing d1 is closer to the preset spacing value d, and the preset spacing value d is 0.2d2. When the first spacing d1 is equal to the preset spacing value d, the support body 310 has good support performance. Therefore, when the first spacing d1 is equal to the preset spacing value d, the value of the first spacing d1 is the ideal value, and at this time, the support effect of the support column 310 is the best. That is, along the direction from the center to the edge of the display panel 10, the closer the value of the first spacing d1 in at least some areas is to the ideal value, the stronger the support capacity of the support column 310 is. The cover plate 400 is less prone to deformation in the edge area, which can effectively improve the Newton ring phenomenon caused by the deformation of the cover plate 400 in the edge area.

Optionally, please continue to refer to FIG. 1. The display panel 10 has a display area, which includes a first display area AA1, a second display area AA2 distributed from the edge to the center thereof, and a third display area AA3 located between the first display area AA1 and the second display area AA2.

The first display area AA1 is adjacent to the outer edge of the display area, that is, the outer edge of the first display area AA1 is the outer edge of the display area, and the first display area AA1 is formed by extending from the outer edge of the display area to the center part of the display area.

The sizes of the first display area AA1, the second display area AA2, and the third display area AA3 are not limited. The sizes of the first display area AA1, the second display area AA2, and the third display area AA3 can be determined based on the Newton ring phenomenon of the same type of the display panel 10 with the same display area size. The Newton ring phenomenon usually occurs at a certain distance from the edge of the display area, that is, the Newton ring phenomenon usually occurs in the third display area AA3.

In some optional embodiments, the first spacing d1 between two adjacent support columns 310 in the first direction within the support assembly 300 within the third display area AA3 satisfies 0.15d2≤d1≤0.0.25d2 so as to improve the support effect of the support column 310 in the third display area AA3 and better improve the Newton ring phenomenon caused by the deformation of the cover plate 400.

Optionally, the values of multiple first spacing d1 within the third display area AA3 can be equal, or the preset spacing value d is equal to 0.18d2. In the area in the third display area AA3 where the distance to the first display area AA1 and the distance to the second display area AA2 are equal, that is, in the middle area of the third display area AA3, the first spacing d1 satisfies d1=d=0.18d2 so as to further enhance the support capacity of the support column 310 in the middle area of the third display area AA3 and better improve the Newton ring phenomenon caused by the deformation of the cover plate 400.

Optionally, within the second display area AA2, in the direction from the second display area AA2 to the third display area AA3, the absolute value of the difference between the first spacing d1 and the preset spacing value d gradually decreases, and the preset spacing value d meets 0.15d2≤d≤0.25d2. Therefore, the closer to the third display area AA3, the closer the first spacing d1 is to the ideal value, and the stronger the support capacity of the support column 310 is, which can improve the Newton ring phenomenon caused by the deformation of the cover plate 400 better.

Optionally, within the first display area AA1, in the direction from the first display area AA1 to the third display area AA3, the absolute value of the difference between the first spacing d1 and the preset spacing value d gradually decreases, and the preset spacing value d meets 0.15d2≤d≤0.25d2. Therefore, the closer to the third display area AA3, the closer the first spacing d1 is to the ideal value, and the stronger the support capacity of the support column 310 is, which can improve the Newton ring phenomenon caused by the deformation of the cover plate 400 better.

In some optional embodiments, as shown in FIGS. 2 to 5, the pixel openings 220 are arranged in an array along the first direction X and the second direction Y, the support assembly 300 is located between adjacent pixel openings 220 in the second direction Y, and multiple support columns 310 in the support assembly 300 are spaced along the first direction X. There is a spacing gap between two adjacent pixel openings 220 in the second direction Y, and the extension size of the spacing gap in the first direction X is greater than its extension size in the second direction Y It should be noted that the first direction X can refer to the row direction of the pixel openings arrangement, and the second direction Y can refer to the column direction of the pixel openings arrangement, of course, the first direction X can also refer to the column direction of the pixel openings arrangement, and the second direction Y can also refer to the row direction of the pixel openings arrangement, without any specific restrictions.

In these optional embodiments, the extension size in the first direction X of the spacing gap between two adjacent pixel openings 220 in the second direction Y is larger than its extension size in the second direction Y. When the support assembly 300 is located between two adjacent pixel openings 220 in the second direction Y, and multiple support columns 310 in the support assembly 300 are spaced along the first direction X, the distribution of the support columns 310 and the pixel openings 220 can be optimized, so that multiple support columns 310 can be provided between the two adjacent pixel openings 220, further improving the support effect of the support column 310.

Optionally, the two adjacent pixel openings 220 along the second direction Y are arranged to be aligned so that the shape of the spacing gap is more regular. Optionally, the pixel openings 220 have the same extension size in the first direction X.

Optionally, the pixel openings 220 of the two adjacent columns are arranged to be misaligned to form an offset in the first direction, with the column direction being the second direction Y. That is, the pixel openings 220 of the previous column located correspondingly between the two adjacent pixel openings 220 in the following column. On the one hand, when a light emitting unit is provided inside the pixel opening 220, the obvious display stripe phenomenon on the display panel 10 can be improved. On the other hand, the support assemblies 300 of the two adjacent columns are misaligned, so that the distribution of multiple support assemblies 300 is more uniform, further improving the support capacity of the support assemblies 300 on the cover plate 400 so that the force on the cover plate 400 is more balanced and the cover plate 400 is less prone to deformation.

When multiple support columns 310 within the support assembly 300 are distributed along the first direction X, the multiple support columns 310 within the support assembly 300 are distributed to be spaced apart or are embedded with each other along the first direction X. The spaced distribution of multiple support columns 310 within the support assembly 300 along the first direction X refers to that multiple support columns 310 within the support assembly 300 in the first direction X are separated from each other completely and are not overlapped with each other.

As shown in FIGS. 2 to 5, in some optional embodiments, multiple support columns 310 within the support assembly 300 are spaced along the first direction X.

In these optional embodiments, the first direction X is the first direction mentioned above, and there is a first gap d1 between two adjacent support columns 310, so that the support column 310 has a simple structure and is convenient for preparation.

In some optional embodiments, as shown in FIGS. 2 to 5, at least two adjacent support columns 310 within the support assembly 300 have opposite first and second mating surfaces 311 and 312. There are various ways to dispose the mutual position relationship between the first and second mating surfaces 311 and 312.

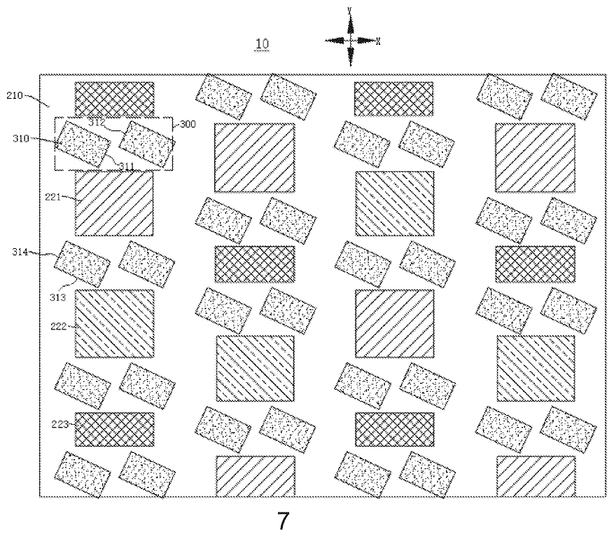

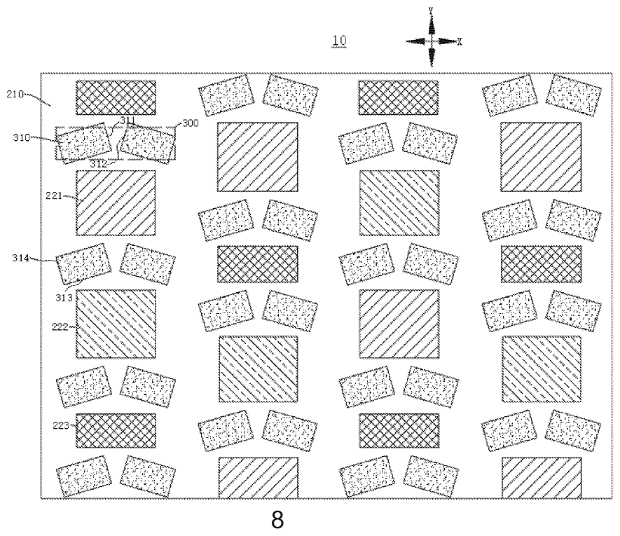

For example, the first mating surface 311 and the second mating surface 312 are parallel to each other, equivalent to that the support assembly 300 is divided into multiple support columns 310 along a reference plane parallel to the first mating surface 311 and the second mating surface 312 and the multiple support columns 310 are distributed to be spaced apart. When the first mating surface 311 and the second mating surface 312 are parallel to each other, as shown in FIGS. 2 to 5, the first mating surface 311 and the second mating surface 312 can be disposed parallel to the second direction Y. Alternatively, as shown in FIGS. 6 and 7, the first mating surface 311 and the second mating surface 312 can intersect with the second direction Y. When the first mating surface 311 and the second mating surface 312 intersect with the second direction Y, the angle between the first mating surface 311, the second mating surface 312 and the second direction Y is less than or equal to 30 degrees, so as to avoid the angle between the first mating surface 311, the second mating surface 312 and the second direction Y being too large, and the extension size of the support column 310 in the second direction Y being too small, which otherwise causes large-area collapse deformation easily during the preparation. The first direction X is perpendicular to the second direction Y.

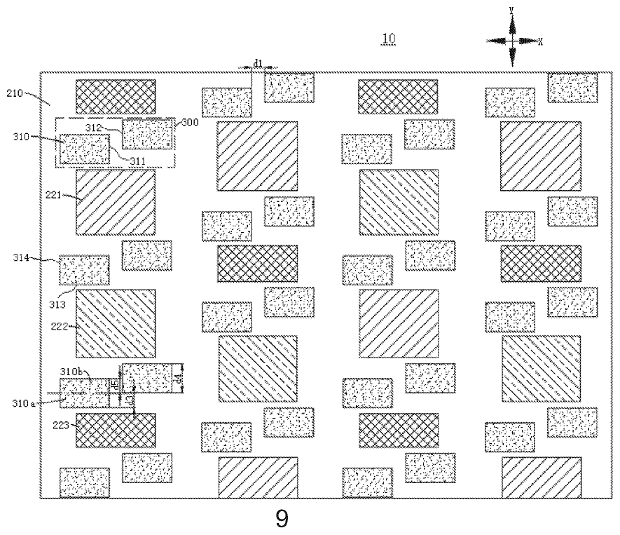

Alternatively, in other optional embodiments, as shown in FIG. 8, the plane of the first mating surface 311 can further intersect with the plane of the second mating surface 312, improving the distribution uniformity of multiple support columns 310 within the support assembly 300.

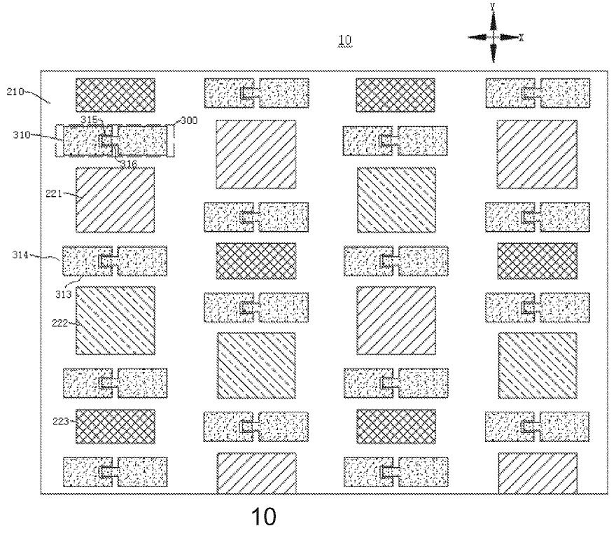

In some optional embodiments, as shown in FIG. 9, when multiple support columns 310 within the support assembly 300 are distributed to be spaced apart along the first direction X, the two adjacent support columns 310 are arranged to be misaligned.

In these optional embodiments, the two adjacent support columns 310 are not aligned in the first direction X, which can improve the uniformity of the distribution of multiple support columns 310 within the support assembly 300 in the first direction X, improve the uniformity of the force on the cover plate 400, and improve the deformation of the cover plate 400 better.

The misaligned arrangement of the two adjacent support columns 310 refers to that the projection of one part of the two adjacent support columns 310 in the first direction X are overlapped, while the projection of the other part in the first direction X are not overlapped. For example, the part where the projections of the two adjacent support columns 310 in the first direction X are overlapped is called as an overlapped part 310b, and the part where the projection of at least one of them in the first direction X is staggered from the projection of the other in the first direction X is called as a misaligned part 310a.

The extension distance of the misaligned part 310a in the second direction Y of the two adjacent support columns 310 within the same support assembly 300 is the misaligned distance d3. The extension width of a single support column 310 in the second direction Y is d4, and the misaligned distance d3 meets 0.35d4≤d3≤0.45d4. The extension distance of the overlapped part 310b in the second direction Y of the two adjacent support columns 310 is d5, then d3=d4−d5.

In these optional embodiments, when the misaligned distance d3 is 35% to 45% of the extension width d4, the misaligned distance d3 being too small can be avoided, which otherwise causes the overlapped part 310b of the two adjacent support columns 310 to be too small, and cannot achieve the goal of multiple support columns 310 within the support assembly 300 being evenly distributed in the first direction X, thereby affecting the support capacity of the entire support assembly 300. This arrangement can further avoid the misalignment distance d3 being too large, and avoid that the two adjacent support columns 310 are not able to effectively utilize the position limiting effect of the first gap d1, which otherwise results in too large deformation amount of the support column 310 during the preparation and thus affect the support capacity of the entire support assembly 300.

Assuming that the extension width d4 of the support column 310 in the second direction Y is 12 μm, the misaligned distance d3 of the misaligned part 310a in the second direction Y of the two adjacent support columns 310 within the support assembly 300 is set to 3 μm, 4 μm, 5 μm, 6 μm, 7 μm and 9 μm respectively, the deformation amount of the cover plate 400 is shown in the table below:

| | | the deformation amount of | |
|---|---|---|---|
| | the misaligned distance | the cover plate | |
| Example 9 | 3 μm | 2.3213 | nm |
| Example 10 | 4 μm | 2.22885 | nm |
| Example 11 | 5 μm | 1.418 | nm |
| Example 12 | 6 μm | 2.2818 | nm |
| Example 13 | 7 μm | 2.1362 | nm |
| Example 14 | 9 μm | 2.2795 | nm |

According to the above table, when the misaligned distance d3 is taken as 3 μm, 4 μm, 6 μm, 7 μm and 9 μm, the deformation amount of the cover plate 400 is relatively large. When the value of the misaligned distance d3 is 5 μm, that is, when 0.35d4≤d3≤0.45d4, the deformation amount of the cover plate 400 is the smallest. Therefore, by setting the misaligned distance d3 reasonably, the support capacity of the support assembly 300 can be improved and the deformation amount of the cover plate can be improved.

Optional, the misaligned distance d3 is 4.5 μm˜5.5 μm. When the misaligned distance d3 is within the above value range, it can avoid that the misaligned distance d3 being too small or too large influences on the support capacity of the support assembly 300.

There are various ways to provide the shape of the support column 310, and the outer contour of the orthogonal projection of the support column 310 on the substrate 100 is polygonal. For example, the outer contour of the orthogonal projection of the support column 310 on the substrate 100 is triangular, quadrilateral, pentagonal, etc. For example, as shown in FIG. 6, the outer contour of the orthogonal projection of the support column 310 on the substrate 100 is trapezoidal. For example, when the support assembly 300 includes two support columns 310, the outer contour of the orthogonal projection of the support column 310 on the substrate 100 can be a right angled trapezoid, and the first and second mating surfaces 311 and 312 can be parallel to each other and intersect with the second direction Y, which is equivalent to cutting the support assembly 300 into two support columns 310 along a direction parallel to the first mating surface 311.

Optionally, in other embodiments, the support assembly 300 may also include three or more support columns 310. Among the three or more support columns 310, the support columns 310 located on both sides of the first direction X can be of a right angled trapezoid, and the support columns 310 located in the middle can be a non-right angled trapezoid, so that the outer contour of the orthogonal projection of the support assembly 300 on the substrate 100 on the whole is rectangular, which can improve the distribution area of the support columns 310.

In other embodiments, as shown in FIGS. 2 to 5, the outer contour of the orthogonal projection of the support column 310 on the substrate 100 can be rectangular, and the orthogonal projection of the support column 310 on the substrate 100 includes the first side 313 and the second side 314 connected to each other. In these optional embodiments, the shape of the support column 310 is more regular, so that the preparation of the support column 310 is simpler.

Optionally, the first side 313 and second side 314 can be formed by the orthogonal projection of the surface of the support column 310 on the substrate 100. For example, when the outer contour of the orthographic projection of the support column 310 on the substrate 100 is rectangular, the support column 310 includes a top surface facing away from the pixel definition layer 200 and four peripheral sides connected to the periphery of the top surface and extending towards the pixel definition layer 200. The first side 313 is formed by the orthographic projection of one of the four peripheral sides on the substrate 100, and the second side 314 is formed by the orthographic projection of the other of the four peripheral sides on the substrate 100. When the orthogonal projection of the support column 310 on the substrate 100 is rectangular, there are various distribution ways of the support column 310. In some embodiments, as shown in FIGS. 2 to 5, the first sides 313 of at least two adjacent support columns 310 in the support assembly 300 along the first direction X are parallel to each other, and the first side 313 is parallel to the first direction X.

In these optional embodiments, two adjacent support columns 310 are arranged to be spaced apart along the first direction X, the first side 313 of the support column 310 is parallel to the first direction X, and the support column 310 is located between adjacent pixel openings along the second direction Y, so that the spacing between the same support column 310 and the pixel openings 220 located on both sides thereof in the second direction Y is the same, and the spacing between the same support column 310 and the pixel openings 220 located on both sides thereof in the second direction Y is relatively far. On the one hand, this facilitates the preparation of the support column 310. On the other hand, when the support column 310 collapses and deforms during the preparation, this can avoid the material of the support column 310 flowing into the pixel opening 220 and affecting the light-emitting of the display panel 10.

In other some embodiments, as shown in FIG. 7, the first sides 313 of at least two adjacent support columns 310 in the support assembly 300 along the first direction X are parallel to each other, and the first side 313 intersects with the first direction X.

In these optional embodiments, the first side 313 of the support column 310 within the support assembly 300 rotates at a predetermined angle relative to the first direction X, and the rotation directions of the two adjacent support columns 310 are the same, so that the two adjacent support columns 310 are arranged in parallel so that the force of the cover plate 400 is more balanced.

In further some embodiments, as shown in FIG. 8, the extension lines of the first sides 313 of at least two adjacent support columns 310 in the support assembly 300 in the first direction X are arranged to be intersected, so that at least two adjacent support columns 310 are arranged in a splayed shape.

In these optional embodiments, the first side 313 of the support column 310 within the support assembly 300 rotates at a predetermined angle relative to the first direction X, and the rotation directions of the two adjacent support columns 310 are opposite, so that the two adjacent support columns 310 are arranged in a splayed shape so that the force of the cover plate 400 is more balanced.

There are various ways to set the lengths of the first side edge 313 and the second side edge 314. In some optional embodiments, as shown in FIG. 7, the angle between the first side 313 and the first direction X is smaller than the angle between the second side 314 and the first direction X, and the length of the first side 313 is greater than the length of the second side 314.

The extension size of the gap in the first direction X between two adjacent pixel openings 220 in the second direction Y is larger than its extension size in the second direction Y. The length of the first side 313 is greater than the length of the second side 314, which can ensure that the size the support column 310 in the first direction X is large enough, thereby ensuring that the size of a single support column 310 is large enough to improve the support capacity of the support assembly 300.

The angle between the first side 313 and the first direction X can be 0, at this time, the first side 313 and the first direction X are arranged to be parallel with each other. Alternatively, the angle between the first side 313 and the first direction X is less than 90 degrees.

In some optional embodiments, the ratio of the first side 313 to the second side 314 of at least one support column 310 is 1.3 to 1.9.

In these optional embodiments, when the preset ratio of the first side 313 to the second side 314 is within the above range, on the one hand, sufficiently large size can be ensured, and the support column 310 with sufficient support force can be ensured.

By changing the four variables: the density of the support columns 310, the length of the first side 313, the length of the second side 314, and the height of the support column 310, and detecting the Newton ring phenomenon on the display panel 10, the following table is obtained:

| | | cross-sectional information of the support columns | | | | |
|---|---|---|---|---|---|---|
| | | inside the support assembly μm | | | | |
| | the density of | | | the height | the ratio of | |
| | the support | the length of | the length of | (including the pixel | the first to | Newton |
| | assembly | the first side | the second side | definition layer) | second sides | ring |
| Example 16 | 18% | 31.6 | 24 | 3.325 | 1.32 | 0.00% |
| Example 17 | 16% | 30.5 | 22.9 | 3.325 | 1.33 | 0.00% |
| Example 18 | 14% | 18 | 12 | 3.325 | 1.50 | 0.00% |
| Example 19 | 15% | 22.8 | 15 | 3.325 | 1.52 | 0.00% |
| Example 20 | 20% | 27.2 | 14 | 3.325 | 1.94 | 0.08% |
| Example 21 | 14% | 27.2 | 11 | 2.975 | 2.47 | 0.09% |
| Example 22 | 19% | 32.5 | 11 | 3.325 | 2.95 | 0.31% |
| Example 23 | 18% | 34.5 | 11 | 3.325 | 3.14 | 0.52% |
| Example 24 | 19% | 34.5 | 11 | 3.325 | 3.14 | 0.59% |
| Example 25 | 26% | 35 | 11 | 3.325 | 3.18 | 0.01% |
| Example 26 | 15% | 14 | 11 | 3.325 | 1.27 | 0.92% |

From Examples 16 to 20 in the above table, it can be seen that in the case of the same height of the support column 310, even if the distribution density of the support columns 310 increases, when the ratio of the first side 313 to the second side 314 is larger than 1.9, a Newton ring phenomenon will still occur. And through the comparison between Example 22 and Example 24, it can be seen that in the case that the height and the distribution density of the support columns 310 remain unchanged, when the ratio of the first side 313 to the second side 314 is greater than 1.9, the length of the first side 313 of the support column 310 continues to be increased, when the ratio of the first side 313 to the second side 314 is greater, the Newton ring phenomenon becomes more severe.

From Example 26, it can be seen that when the ratio of the first side 313 to the second side 314 is less than 1.3, the Newton ring occurs easily in the display panel 10. Furthermore, from Examples 21 to 26, it can be seen that when the length of the second side 314 is equal to 11 μm, the Newton ring occurs easily. Therefore, the length of the second side 314 greater than 11 μm can improve the Newton ring problem.

Assuming the length of the first side 313 of the support column 310 is 16 μm, the length of the second side 314 of the support column 310 is set to 12 μm, 14 μm and 16 μm respectively, the deformation amount of the cover plate 400 is shown in the table below:

| | | the deformation | |
|---|---|---|---|
| | the length of the | amount of the | improvement |
| | second side | cover plate | rate |
| Example 27 | 12 μm | 2.3466 nm | 100% |
| Example 28 | 14 μm | 2.0823 nm | 112.7% |
| Example 29 | 16 μm | 1.8956 nm | 128.3% |

Assuming the length of the second side 314 of the support column 310 is 12 μm, the length of the first side 313 of the support column 310 is set to 16 μm, 17 μm and 18 μm respectively, the deformation amount of the cover plate 400 is shown in the table below:

| | | the deformation | |
|---|---|---|---|
| | the length of the | amount of the | improvement |
| | first side | cover plate | rate |
| Example 30 | 16 μm | 2.3466 nm | 100% |
| Example 31 | 17 μm | 2.2438 nm | 104.6% |
| Example 32 | 18 μm | 2.1371 nm | 109.8% |

According to the above two tables, when the length of the first side 313 is 16 μm and the length of the second side 314 approaches the length of the first side 313, the deformation amount of the cover plate 400 gradually decreases, and the deformation rate of the cover plate 400 gradually increases. When the length of the second side 314 is 12 μm and the length of the first side 313 gradually increases, the deformation amount of the cover plate 400 gradually increases.

By synthesizing the above two tables, it can be seen that when the length of the second side 314 and the first side 313 increase by the same size, the increasing of the length of the second side 314 significantly raises the deformation amount of the cover plate 400. Therefore, it is ensured that the length of the second side 314 is within the appropriate range, that is, when the second side 314 is greater than 11 μm, the support capacity of the support column 310 is improved better and the deformation of the cover plate 400 is improved better.

Optional, the length of the second side 314 is greater than 11 μm and less than or equal to 20 μm, which can improve the Newton ring phenomenon caused by the deformation of the cover plate 400 better.

Optionally, the length of the first side 313 of the support column 310 can be 15 μm˜18 μm. Optionally, the sum of the lengths of the first side 313 of multiple support columns 310 within the support assembly 300 can be 30 μm˜36 μm. When the size of the support column 310 is within the above range, it can not only ensure that the support column 310 has sufficient support force, but also ensure sufficient spacing between the support column 310 and the pixel opening 220.

In display panel 10, there are various ways to set the ratio values of the first side 313 to the second side 314 of multiple support columns 310. For example, the ratio values of the first side 313 to the second side 314 of multiple support columns 310 are all equal.

Alternatively, in other optional embodiments, in the direction from the center to the edge of the display panel 10, the absolute value of the difference between the ratio of the first side 313 to the second side 314 and the preset ratio gradually decreases, and the preset ratio is 1.6. That is, the closer to the edge area, the closer the ratio of the first side 313 to the second side 314 is to the ideal value, and the stronger the support capacity of the support column 310 is, which can improve the Newton ring phenomenon better.

Optionally, when the display panel 10 includes the first display area AA1, the second display area AA2, and third display area AA3 mentioned above, the ratio of the first side 313 to the second side 314 of the support column 310 in the third display area AA3 is 1.3˜1.9, so that the support column 310 in the third display area AA3 to have sufficient support force, improving the Newton ring phenomenon better.

Optionally, within the first display area AA1, along the direction from the first display area AA1 to the third display area AA3, the absolute value of the difference between the ratio of the first side 313 to the second side 314 and the preset ratio gradually decreases, and the preset ratio is 1.6. That is, in the first display area AA1, the closer to the third display area AA3, the stronger the support capacity of the support column 310 is, which can improve the Newton ring phenomenon better.

Optionally, within the second display area AA2, along the direction from the second display area AA2 to the third display area AA3, the absolute value of the difference between the ratio of the first side 313 to the second side 314 and the preset ratio gradually decreases. That is, in the second display area AA2, the closer to the third display area AA3, the stronger the support capacity of the support column 310 is, which can improve the Newton ring phenomenon better.

In some embodiments, the distribution density of the support columns 310 in the third display area AA3 is greater than that in the first display area AA1 and/or the second display area AA2.

The distribution density of the support columns 310 can be the ratio of the distribution number of the support columns 310 to the area of the display area where they are located. The distribution density of the support columns 310 can also be the ratio of the distribution area of the support columns 310 to the area of the display area where they are located.

When the distribution density of the support columns 310 in the third display area AA3 is greater than the distribution density of the support columns 310 in the first display area AA1, the support force of the support column 310 in the third display area AA3 is stronger, which can improve the Newton ring phenomenon.

When the distribution density of the support columns 310 in the third display area AA3 is greater than the distribution density of the support columns 310 in the second display area AA2, the support force of the support column 310 in the third display area AA3 is stronger, which can improve the Newton ring phenomenon.

In other embodiments, as shown in FIG. 10, in at least two adjacent support columns 310 within the support assembly 300, one of which is recessed facing the surface of the other to form a groove 315, while the other protrudes to form a protruding part 316, and the protruding part 316 is located in the groove 315.

In these optional embodiments, the groove 315 of one of the support columns 310 can provide a position limit to the protruding part 316 of the other of the support columns 310, so as to reduce the collapse deformation of the protruding part 316 during the preparation, thereby reducing the difference between the actual shape and the design shape of the support column 310, improving the support capacity of the support column 310, and improving the deformation of the cover plate better.

In these optional embodiments, at least part of the support assembly further includes a support column, wherein the total size of the support assembly including two or more spaced support columns is the same as the total size of the support assembly including one support column.

The embodiments of the present application in the second aspect further provide a display device including a display panel 10 of any of the embodiments in the first aspect mentioned above. As the display device of the embodiments of the present application includes the display panel 10 mentioned above, the display device of the present application embodiment has the beneficial effect of the display panel 10 mentioned above, and will not be further described here.

The display device in the embodiments of the present application includes but is not limited to the devices with display function such as mobile phone, Personal Digital Assistant (PDA), tablet, e-book, television, entrance guard, smart fixed-line telephone, and console.

What is claimed is:

1. A display panel, comprising:
a substrate;
a pixel definition layer provided on the substrate, the pixel definition layer comprising an isolation structure and a plurality of pixel openings formed and enclosed by the isolation structure;
a support assembly provided on a side of the isolation structure facing away from the substrate and located between two pixel openings which are at least partially adjacent, at least part of the support assembly comprising two or more support columns spaced apart; and
a cover plate located on a side of the support assembly facing away from the pixel definition layer.

2. The display panel according to claim 1, wherein the support assembly has a first spacing d1 between at least two adjacent support columns in a first direction, an extension size of the support column in the first direction is d2, and the first spacing d1 meets 0.15d2≤d1≤0.25d2;
along a direction from a center of the display panel to an edge of the display panel, an absolute value of a difference between the first spacing d1 and a preset spacing value d gradually decreases in at least some areas, and the preset spacing value d is 0.2d2.

3. The display panel according to claim 2, wherein the display panel comprises a display area, the display area comprises a first display area and a second display area distributed along a direction from the edge to the center of the display panel, and a third display area located between the first display area and the second display area, in the support assembly within the third display area, the first spacing d1 between the two adjacent support columns in the first direction meets 0.15d2≤d1≤0.25d2.

4. The display panel according to claim 3, wherein in a direction from the second display area to the third display area, in the support assembly within the second display area, an absolute value of a difference between the first spacing d1 between the two adjacent support columns in the first direction and the preset spacing value d gradually decreases;
and/or, in a direction from the first display area to the third display area, in the support assembly within the first display area, an absolute value of a difference between the first spacing d1 between two adjacent support columns in the first direction and the preset spacing value d gradually decreases.

5. The display panel according to claim 3, wherein a distribution density of the support columns within the third display area is greater than a distribution density of the support columns within the first display area and/or the second display area.

6. The display panel according to claim 1, wherein the plurality of pixel openings are arranged in an array along the first and second directions, the second direction intersects with the first direction, the support assembly is located between two adjacent pixel openings along the second direction, and multiple support columns are arranged along the first direction within the support assembly, wherein a spacing gap is provided between the two adjacent pixel openings in the second direction, and an extension size of the spacing gap in the first direction is greater than an extension size of the spacing gap in the second direction.

7. The display panel according to claim 6, wherein multiple support columns are arranged to be spaced apart along the first direction within the support assembly.

8. The display panel according to claim 7, wherein at least two adjacent support columns within the support assembly have opposite first and second mating surfaces, the first and second mating surfaces are parallel to each other, or a plane where the first mating surface is located intersects with a plane where the second mating surface is located;
alternatively, the first and second mating surfaces are parallel to each other, an angle between the first mating surface and the second direction is less than or equal to 30 degrees, and the second direction is perpendicular to the first direction.

9. The display panel according to claim 6, wherein two adjacent support columns are arranged to be misaligned within the support assembly.

10. The display panel according to claim 9, wherein within the support assembly, an extension distance of misaligned parts of the two adjacent support columns in the second direction is a misaligned distance d3, an extension width of the support column in the second direction is d4, and the misaligned distance d3 meets 0.35d4≤d3≤0.45d4.

11. The display panel according to claim 7, wherein an outer contour of an orthogonal projection of the support column on the substrate is a polygon.

12. The display panel according to claim 11, wherein the outer contour of the orthogonal projection of the support column on the substrate is rectangular and has a first side and a second side connected to each other.

13. The display panel according to claim 12, wherein extension lines of the first sides of at least two adjacent support columns in the first direction within the support assembly are arranged to intersect with each other, so that at least two adjacent support columns are arranged in a splayed shape;
alternatively, the first sides of at least two adjacent support columns in the first direction within the support assembly are parallel to each other, and the first side intersects with a row direction;
alternatively, the first sides of at least two adjacent support columns in the first direction within the support assembly are parallel to each other, and the first side is parallel to the row direction.

14. The display panel according to claim 12, wherein an angle between the first side and the first direction is less than an angle between the second side and the first direction, and a length of the first side is greater than a length of the second side.

15. The display panel according to claim 12, wherein a ratio of the first side to the second side of at least one of the supporting columns is 1.3˜1.9.

16. The display panel according to claim 15, wherein in a direction from a center of the display panel to an edge of the display panel, an absolute value of a difference between the ratio of the first side to the second side and the preset ratio gradually decreases in at least some areas, and the preset ratio is 1.6.

17. The display panel according to claim 15, wherein the display panel comprises a display area, the display area comprises a first display area and a second display area arranged in a direction from the edge of the display panel to the center of the display panel, and a third display area located between the first display area and the second display area, and in the support assembly within the third display area, the ratio of the first side to the second side of the support column is 1.3˜1.9.

18. The display panel according to claim 17, wherein in a direction from the second display area to the third display area, in the support assembly within the second display area, an absolute value of a difference between the ratio of the first side to the second side of the support column and the preset ratio gradually decreases;
and/or, in a direction from the first display area to the third display area, in the support assembly within the first display area, an absolute value of a difference between the ratio of the first side to the second side of the support column and the preset ratio gradually decreases;
a distribution density of the support columns within the third display area is greater than a distribution density of the support columns within the first display area and/or the second display area.

19. The display panel according to claim 1, wherein in at least two adjacent support columns within the support assembly, one of the at least two adjacent support columns is recessed facing a surface of the other of the at least two adjacent support columns to form a groove, the other of the at least two adjacent support columns protrudes to form a protruding part, and the protruding part is located in the groove.

20. The display panel according to claim 19, wherein at least part of the support assembly further comprises one support column, wherein a total size of the support assembly comprising two or more support columns spaced apart is the same as a total size of the support assembly comprising one support column.
